(19) United States
(12) Patent Application Publication
(10) Pub. No.: US 2020/0127115 A1
(43) Pub. Date: Apr. 23, 2020

(54) MANUFACTURING METHOD OF HIGH ELECTRON MOBILITY TRANSISTOR

(71) Applicant: GlobalWafers Co., Ltd., Hsinchu (TW)

(72) Inventors: Hsien-Chin Chiu, Hsinchu (TW); Ying-Ru Shih, Hsinchu (TW)

(73) Assignee: GlobalWafers Co., Ltd., Hsinchu (TW)

(21) Appl. No.: 16/166,160

(22) Filed: Oct. 22, 2018

(51) Int. Cl. H01L 29/66; H01L 21/324; H01L 21/02; H01L 29/20; H01L 29/205

(52) U.S. Cl. CPC H01L 29/66462; H01L 21/3245; H01L 21/0254; H01L 29/2003; H01L 21/30621; H01L 21/02458; H01L 21/02381; H01L 21/0262; H01L 29/205

(57) ABSTRACT

A manufacturing method of a high electron mobility transistor includes providing an epitaxial stacked structure, wherein the epitaxial stacked structure includes a semiconductor substrate, a buffer layer formed on the semiconductor substrate, a channel layer formed on the buffer layer, an intermediate layer formed on the channel layer, and a barrier layer formed on the intermediate layer; forming a source and a drain on the barrier layer; performing a microwave annealing process, wherein the conditions of the microwave annealing process include a temperature between 450° C. and 550° C., a frequency between 5.8 GHz and 6.2 GHz, and a time between 150 seconds and 250 seconds; and forming a gate on the barrier layer between the source and the drain.

### TECHNICAL FIELD

The present invention relates to a method of manufacturing a transistor, and more particularly to a manufacturing method of a high electron mobility transistor.

### BACKGROUND

In the field of integrated circuits, group III-V semiconductor compounds are often used to form various semiconductor devices, such as high power field-effect transistors, high efficiency transistors, or high electron mobility transistors (HEMT), etc. A high electron mobility transistor is a field effect transistor that can use a junction between two materials with different energy gaps as a channel, so that the channel has a two-dimensional electron gas (2DEG) with high electron mobility. In recent years, a high electron mobility transistor has attracted attention due to its high power performance.

However, the high electron mobility transistor is usually manufactured by a high temperature epitaxial process, wherein the high temperature facilitates indium to diffuse into the two-dimensional electron gas in the channel, resulting in lattice and impurity scattering and therefore causing the decrease in electron mobility of the device. In addition, the current high electron mobility transistor still has problems of leakage current and poor roughness of the epitaxial interface. Such defects may affect the subsequently formed device and result in poor device yield.

Therefore, how to reduce the lattice scattering, leakage current and epitaxial interface roughness to improve the device yield is one of the current problems to be solved.

### SUMMARY

The present invention provides a manufacturing method of a high electron mobility transistor that can improve the problems of lattice scattering, leakage current, and epitaxial interface roughness caused by the epitaxial process.

The present invention provides a manufacturing method of a high electron mobility transistor that includes providing an epitaxial stacked structure, wherein the epitaxial stacked structure includes a semiconductor substrate, a buffer layer formed on the semiconductor substrate, a channel layer formed on the buffer layer, an intermediate layer formed on the channel layer, and a barrier layer formed on the intermediate layer; forming a source and a drain on the barrier layer; performing a microwave annealing process; and forming a gate on the barrier layer between the source and the drain. The conditions of the microwave annealing process include a temperature between 450° C. and 550° C., a frequency between 5.8 GHz and 6.2 GHz, and a time between 150 seconds and 250 seconds.

In an embodiment of the present invention, a power of the microwave annealing process is between 2.7 kW and 2.9 kW.

In an embodiment of the present invention, an atmosphere of the microwave annealing process is nitrogen (N₂).

In an embodiment of the present invention, a root mean square roughness (RMS) of the source and the drain is between 4.56 nm and 6.79 nm.

In an embodiment of the present invention, when a voltage V_{D} applied to the drain is 10 V, a leakage current of the high electron mobility transistor is 9.28×10⁻⁴ mA/mm or less.

In an embodiment of the present invention, the high electron mobility transistor has a current reduction rate of 10% or less due to current collapse.

In an embodiment of the present invention, a contact resistance of the high electron mobility transistor is between 4.02×10⁻⁵ Ω/cm² and 5.32×10⁻⁵ Ω/cm².

In an embodiment of the present invention, a material of the barrier layer is InAlN, a thickness of the barrier layer is between 8 nm and 10 nm, and an indium content of the barrier layer after the microwave annealing process is between 0.17% and 0.18%.

In an embodiment of the present invention, a material of the intermediate layer is AlN, and a thickness of the intermediate layer is between 0.5 nm and 2 nm.

Based on the above, the manufacturing method of a high electron mobility transistor of the present invention includes a microwave annealing process, and thus, the present invention can avoid the lattice scattering, the poor intergranular interface roughness and the leakage current problems of a high electron mobility transistor due to the diffusion of atoms during the epitaxial process. Therefore, the electron mobility and the yield of the high electron mobility transistor can be improved.

Several exemplary embodiments accompanied with figures are described in detail below to further describe the disclosure in details.

### BRIEF DESCRIPTION OF THE DRAWINGS

FIG. 1A to FIG. 1C are schematic cross-sectional views of a manufacturing process of a high electron mobility transistor according to an embodiment of the present invention.

FIG. 2 shows transmission electron microscope (TEM) images of an experimental example and a comparative example.

FIG. 3 shows energy dispersive spectrometer (EDS) graphs of the experimental example and the comparative example.

FIG. 4 shows DC measurement graphs of the experimental example and the comparative example.

FIG. 5 shows pulse measurement graphs of the experimental example and the comparative example.

### DETAILED DESCRIPTION OF DISCLOSED EMBODIMENTS

The disclosure is described below with reference to the drawings, but the disclosure may be implemented in many different forms and is not limited to the description of the embodiments. In the drawings, for clarity, the dimensions and relative dimensions of the various layers and regions may not be drawn to scale. For the sake of easy understanding, the same elements in the following description will be denoted by the same reference numerals. In the present specification, a range represented by “a numerical value to another numerical value” is a schematic representation for avoiding listing all of the numerical values in the range in the specification. Therefore, the recitation of a specific numerical range covers any numerical value in the numerical range and a smaller numerical range defined by any numerical value in the numerical range, as is the case with the any numerical value and the smaller numerical range stated explicitly in the specification.

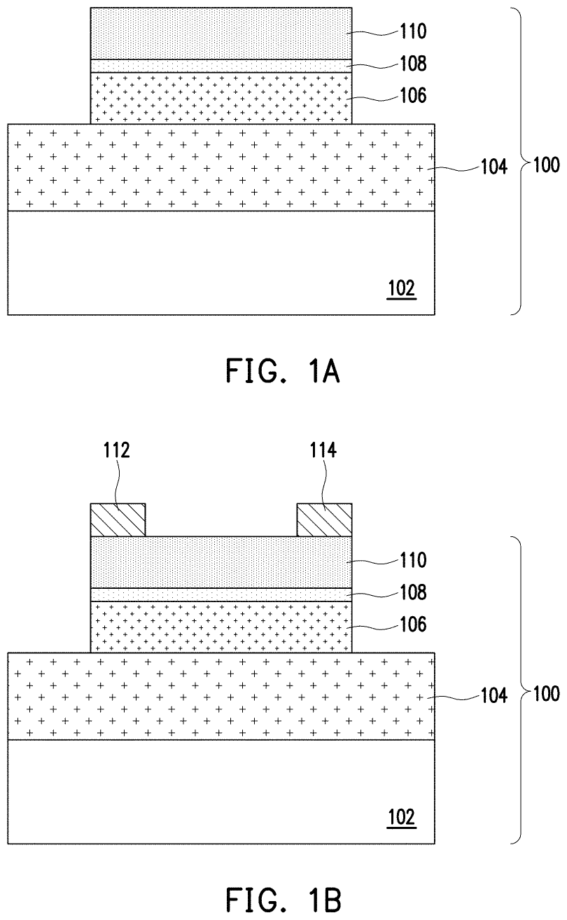

FIG. 1A to FIG. 1C are schematic cross-sectional views of a manufacturing process of a high electron mobility transistor according to an embodiment of the present invention.

Referring to FIG. 1A, an epitaxial stacked structure 100 is provided. The epitaxial stacked structure 100 includes a semiconductor substrate 102, a buffer layer 104 formed on the semiconductor substrate 102, a channel layer 106 formed on the buffer layer 104, an intermediate layer 108 formed on the channel layer 106, and a barrier layer 110 formed on the intermediate layer 108. In the present embodiment, the material of the semiconductor substrate 102 includes sapphire, silicon (Si), silicon carbide (SiC), gallium nitride (GaN), zinc oxide (ZnO), gallium arsenide (GaAs) or silicon on insulator (SOI). The material of the buffer layer 104 and the channel layer 106 includes gallium nitride. The material of the intermediate layer 108 is, for example, AlN, and the thickness of the intermediate layer 108 is between 0.5 nm and 2 nm. The material of the barrier layer 110 is, for example, InAlN, and the thickness of the barrier layer 110 is between 8 nm and 10 nm. For example, when the material of the barrier layer 110 is InAlN, a high electron mobility transistor having a better lattice matching degree and a higher drain current density can be obtained in the subsequent processes.

Referring to FIG. 1B, a source 112 and a drain 114 are formed on the barrier layer 110. In the present embodiment, the material of the source 112 and the drain 114 is Ohmic metal such as Ti/Al/Ti, Ti/Al/Ni/Au, Al/Si/Cu or the like. The formation method of the source 112 and the drain 114 may be a chemical vapor deposition, a physical vapor deposition, or other suitable formation methods, but the present invention is not limited thereto.

Next, a microwave annealing process is performed. In the present embodiment, the conditions of the microwave annealing process include: a temperature between 450° C. and 550° C., a frequency between 5.8 GHz and 6.2 GHz, and a time between 150 seconds and 250seconds. The power of the microwave annealing process is between 2.7 kW and 2.9 kW. The atmosphere of the microwave annealing process is nitrogen. Accordingly, the above microwave annealing process is annealed in a lower temperature manner than a conventional high temperature annealing process such as rapid thermal annealing (RTA) process.

For example, the barrier layer 110 after the microwave annealing process has an indium content between 0.17% and 0.18%, thereby avoiding lattice and impurity scattering caused by indium diffusion due to high temperature annealing, reducing the mobility problem of the subsequently formed high electron mobility transistor, improving the yield of the high electron mobility transistor, and providing a higher degree of lattice matching. Specifically, if the indium content is 0.17%, the lattice is approximately the same as the lattice of the gallium nitride. If the indium content is less than 0.17% or greater than 0.18%, the lattice mismatch will occur, the carrier concentration will be reduced, and the defects will be increased.

On the other hand, the time of the microwave annealing process is between 150 seconds and 250 seconds, so the material can absorb enough energy uniformly. For example, if the time of the microwave annealing process is less than 150 seconds, the time for the material to absorb energy will be too short, resulting in an incomplete reaction. If the time of the microwave annealing process is more than 250 seconds, the material will absorb too much energy, resulting in excessive reaction between materials.

For example, the root mean square roughness of the source 112 and the drain 114 is between 4.56 nm and 6.79 nm, whereby a high electron mobility transistor with better yield can be obtained.

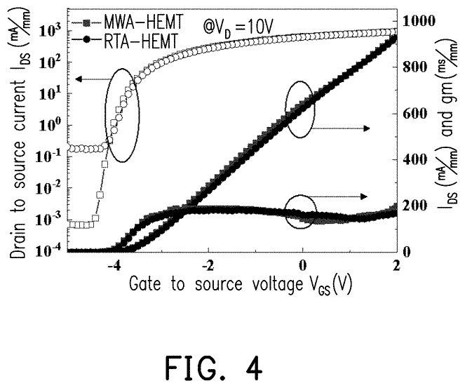

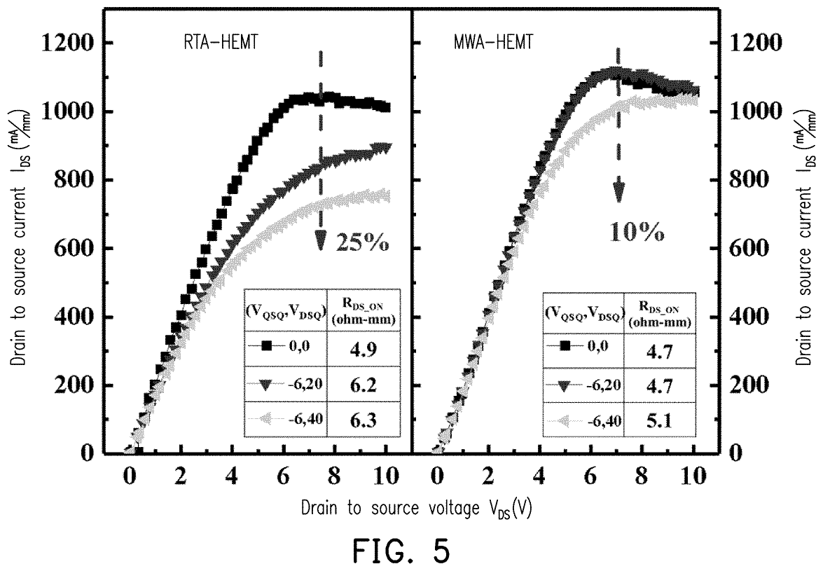

Referring to FIG. 1C, a gate 116 is formed on the barrier layer 110 between the source 112 and the drain 114. For example, the formation method of the gate 116 may be a chemical vapor deposition, a physical vapor deposition, or other suitable formation methods. So far, the fabrication of the high electron mobility transistor is substantially completed. Referring to FIG. 4 (left side), in the embodiment that the voltage V_{D} applied to the drain 114 is 10 V, the leakage current of the high electron mobility transistor is 9.28×10⁻⁴ mA/mm or less. Further, as shown in FIG. 5, the current reduction rate of the high electron mobility transistor caused by the current collapse is 10% or less, and the contact resistance of the high electron mobility transistor is between 4.02×10⁻⁵ Ω/cm² and 5.32×10⁻⁵ Ω/cm². Therefore, the high electron mobility transistor that is manufactured by the microwave annealing process can avoid the lattice and impurity scattering, the poor epitaxial interface roughness and the leakage current problems due to the diffusion of atoms during the epitaxial process, and accordingly enhance the electron mobility and the yield of the high electron mobility transistor.

The device characteristic between the high electron mobility transistor manufactured by the microwave annealing process (hereinafter abbreviated as MWA-HEMT) and the high electron mobility transistor manufactured by the conventional rapid thermal annealing process (hereinafter abbreviated as RTA-HEMT) will be compared in the following.

### EXPERIMENTAL EXAMPLE

### Manufacturing a MWA-HEMT

First, a GaN buffer layer, a 2.5 μm GaN channel layer, a 1.5 nm AlN intermediate layer, and a 10 nm In_{0.18}Al_{0.82}N barrier layer were sequentially formed on a silicon substrate by a metal-organic chemical vapor deposition (MOCVD) process. Thereafter, a reactive ion etching (RIE) process was performed to manufacture a device with mesa isolation. Next, a Ti/Al/Ti (25 nm/150 nm/15 nm) metal layer was formed as source/drain on the barrier layer by electron beam evaporation.

Then, a microwave annealing process was performed under nitrogen atmosphere at a frequency of about 6 GHz, a temperature of 550° C., and a time of 200 seconds. Thereafter, a Ni/Au (25 nm/80 nm) gate having a width of 1 μm was formed on the barrier layer. Next, a SiO₂ protective layer was formed.

### COMPARATIVE EXAMPLE

### Manufacturing a RTA-HEMT

The same process as in the experimental example was used, but the microwave annealing process was changed to an 875° C. rapid thermal annealing process for 35 seconds under nitrogen atmosphere.

<Analysis>

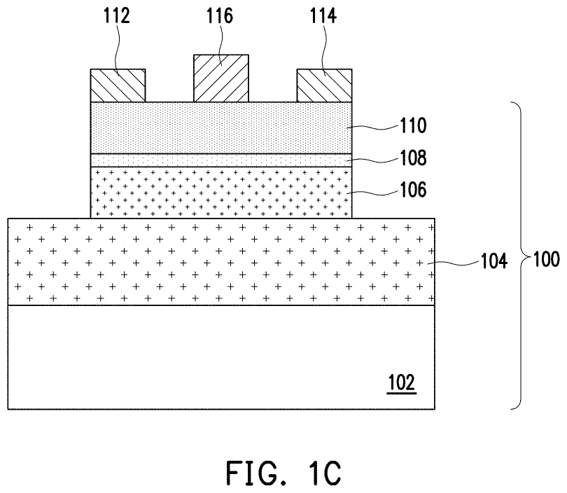

FIG. 2 shows transmission electron microscope images of the experimental example and the comparative example.

Please referring to FIG. 2, the metal surface of the RTA-HEMT on the right side is obviously rougher than the MWA-HEMT on the left side, so the high temperature of the rapid thermal annealing process can cause the aggregation of metal alloy and enable the surface roughness of the source/drain of the comparative example become large.

Then, the surface roughness of the experimental example and the comparative example was measured by atomic force microscopy. The root mean square (RMS) roughness of the experimental example is 6.79 nm, and the root mean square (RMS) roughness of the comparative example is 115 nm. From the measurement results, it can be proved that the experimental example using the microwave annealing process has obvious effects in reducing the surface roughness.

Further, using the measurement method of transmission line method (TLM), the contact resistances of the experimental example and the comparative example are measured to be 4.02×10⁻⁵ Ω/cm² and 4.29×10⁻⁵ Ω/cm², respectively. From the measurement results, it can be proved that the experimental example using the microwave annealing process has obvious effects in reducing the contact resistance.

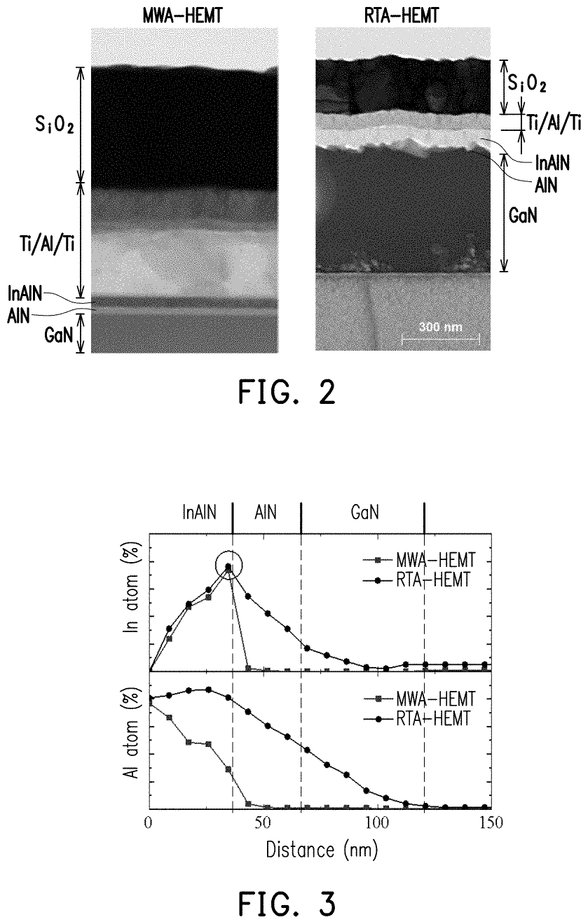

Further, the EDS analysis was performed on the high electron mobility transistor of the experimental example and the comparative example to obtain FIG. 3. As shown in FIG. 3, aluminum (Al) and indium (In) in the barrier layer of the experimental example do not diffuse to the channel layer, but the aluminum and indium in the barrier layer of the comparative example have diffused to the channel layer. Therefore, the present invention can solve the alloy scattering caused by the out-diffusion of indium and aluminum in the conventional epitaxial process, so as to avoid the decrease in the electron mobility of the high electron mobility transistor.

In addition to the above analysis, the experimental example and the comparative example were subjected to DC measurement, and the results were shown in FIG. 4, wherein the voltage V_{D} applied to the drain was 10V. As shown in FIG. 4, the leakage current of the high electron mobility transistor of the experimental example is about 9.28×10⁻⁴ mA/mm or less; the leakage current of the high electron mobility transistor of the comparative example is as high as 2.12×10⁻¹ mA/mm. Therefore, as compared with that of the comparative example, the leakage current of the experimental example in the OFF state is small, and the problem that RTA-HEMT is easy to have an incompletely turned off transistor can be solved. On the other hand, gm in FIG. 4 represents the transconductance of the device, the so-called transconductance indicates the ratio of the current change value at the output terminal to the voltage change value at the input terminal, and from the DC measurement in FIG. 4, it can be found that the IDS and gm graphs of the experimental example and the comparative example are almost indistinguishable from each other, indicating that the dynamic characteristics of the experimental example is similar to that of the comparative example. In other words, a low-temperature annealing microwave annealing process does not affect the device characteristics of the high electron mobility transistor, and is capable of further improving the low yield caused by the leakage current.

In addition, the experimental example and the comparative example were subjected to pulse measurement, and the results were shown in FIG. 5, wherein the measurement conditions of the pulse measurement included: a pulse width of 2 μs, a pulse period of 200 μs, gate and drain static biases of −5V, a drain static bias from 0V to 40V with 20V each step.

As shown in FIG. 5, the current reduction rate of the comparative example is about 25%, and the current reduction rate of the experimental example is about 10%. Therefore, in comparison, the current collapse of the comparative example is severe, and the experimental example can solve the current collapse problem caused by the defects generated by the high-temperature process in the comparative example.

On the other hand, FIG. 5 further indicates the on-resistance (R_{DS_ON}) of the high electron mobility transistor as a function of bias voltage such as gate static bias V_{GSQ} (gate stress Quiescent, GSQ) and source static bias V_{DSQ} (drain stress Quiescent, DSQ). Specifically, when V_{GSQ} and V_{DSQ} are respectively 0 V, the on-resistance of the experimental example is 4.7 Ω·mm, and the on-resistance of the comparative example is 4.9 Ω·mm; when V_{GSQ} is −6 V and V_{DSQ} is 20 V, the on-resistance of the experimental example is 4.7 Ω·mm, and the on-resistance of the comparative example is 6.2 Ω·mm; when V_{GSQ} was −6 V and V_{DSQ} was 40 V, the on-resistance of the experimental example was 5.1 Ω·mm, and the on-resistance of the comparative example was 6.3 Ω·mm. That is to say, the experimental example has a lower on-resistance, whereby the current collapse phenomenon of the high electron mobility transistor can be reduced.

In summary, the manufacturing method of a high electron mobility transistor of the present invention includes a microwave annealing process, and thus, the present invention can avoid the lattice scattering, the poor intergranular interface roughness and the leakage current problems of a high electron mobility transistor due to the diffusion of atoms during the epitaxial process. Therefore, the electron mobility and the yield of the high electron mobility transistor can be improved.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A manufacturing method of a high electron mobility transistor, comprising:
providing an epitaxial stacked structure, wherein the epitaxial stacked structure comprises a semiconductor substrate, a buffer layer formed on the semiconductor substrate, a channel layer formed on the buffer layer, an intermediate layer formed on the channel layer, and a barrier layer formed on the intermediate layer;
forming a source and a drain on the barrier layer;
performing a microwave annealing process, wherein conditions for the microwave annealing process comprise: a temperature between 450° C. and 550° C., a frequency between 5.8 GHz and 6.2 GHz, and a time between 150 seconds and 250 seconds; and
forming a gate on the barrier layer between the source and the drain.

2. The manufacturing method of claim 1, wherein a power of the microwave annealing process is between 2.7 kW and 2.9 kW.

3. The manufacturing method of claim 1, wherein an atmosphere of the microwave annealing process is nitrogen (N₂).

4. The manufacturing method of claim 1, wherein a root mean square roughness (RMS) of the source and the drain is between 4.56 nm and 6.79 nm.

5. The manufacturing method of claim 1, wherein when a voltage applied to the drain is 10 V, a leakage current of the high electron mobility transistor is 9.28×10⁻⁴ mA/mm or less.

6. The manufacturing method of claim 1, wherein the high electron mobility transistor has a current reduction rate of 10% or less due to current collapse.

7. The manufacturing method of claim 1, wherein a contact resistance of the high electron mobility transistor is between 4.02×10⁻⁵ Ω/cm² and 5.32×10⁻⁵ Ω/cm².

8. The manufacturing method of claim 1, wherein a material of the barrier layer is InAlN, a thickness of the barrier layer is between 8 nm and 10 nm, and an indium content of the barrier layer after the microwave annealing process is between 0.17% and 0.18%.

9. The manufacturing method of claim 1, wherein a material of the intermediate layer is AlN, and a thickness of the intermediate layer is between 0.5 nm and 2 nm.
